(19) United States
(12) Patent Application Publication
(10) Pub. No.: US 2024/0322713 A1
(43) Pub. Date: Sep. 26, 2024

(54) ELECTROSTATIC CHUCK AND THIN FILM DEPOSITION APPARATUS INCLUDING THE SAME

(71) Applicant: Samsung Display Co., LTD., Yongin-si (KR)

(72) Inventors: MINCHUL SONG, Yongin-si (KR); MINGOO KANG, Yongin-si (KR); JUNHYEUK KO, Yongin-si (KR); Eui Gyu KIM, Yongin-si (KR); Sukha RYU, Yongin-si (KR); SANGHEON JEON, Yongin-si (KR)

(73) Assignee: Samsung Display Co., LTD., Yongin-si (KR)

(21) Appl. No.: 18/396,845

(22) Filed: Dec. 27, 2023

(30) Foreign Application Priority Data
Mar. 20, 2023 (KR) 10-2023-0035751

(51) Int. Cl. H02N 13/00; B05C 13/00; B05C 21/00

(52) U.S. Cl. CPC H02N 13/00; B05C 13/00; B05C 21/005

(57) ABSTRACT

A thin film deposition apparatus according to an embodiment includes a chamber, a deposition source disposed in a chamber and that supplies a deposition material to the substrate, a mask assembly comprising pattern holes through which the deposition material passes, and an electrostatic chuck facing the mask assembly and that fixes the substrate. The electrostatic chuck comprises a body that supports the substrate, an insulating layer disposed on the body, a first electrode disposed in the insulating layer and spaced apart from the body by a first distance, a second electrode disposed in the insulating layer and spaced apart from the body by a second distance, and a conductive layer disposed in the insulating layer and spaced apart from the body by a third distance. The first electrode and the second electrode are supplied with different voltages, and the third distance is greater than the first distance.

### CROSS-REFERENCE TO RELATED APPLICATION(S)

This application claims priority to and benefits of Korean Patent Application No. 10-2023-0035751 under 35 U.S.C. § 119, filed in the Korean Intellectual Property Office on Mar. 20, 2023, the entire contents of which are incorporated herein by reference.

### BACKGROUND

### 1. Technical Field

The disclosure relates to an electrostatic chuck and a thin film deposition apparatus including the same.

### 2. Description of the Related Art

In manufacturing a display device, a mask for deposition may be used.

In a deposition process for forming an emission layer, an electrode layer, and the like on a substrate, a metal mask such as a fine metal mask and an open mask may be used.

For example, the substrate may be arranged on a mask formed with a predetermined or selected pattern, and material of the emission layer may be deposited on the substrate by passing through the pattern of the mask.

As the substrate becomes larger, sagging of the center part due to gravity, substrate drop, and slippage may occur, so electrostatic chuck (ESC) using electrostatic force may be used to fix the substrate.

### SUMMARY

The substrate can be fixed by the electrostatic force of the electrostatic chuck.

At this time, a part of the mask may be adsorbed to the substrate by the electrostatic force of the electrostatic chuck.

Alignment positions of the substrate and the mask may be shifted in a subsequent process, and thus pixel position accuracy may deteriorate, resulting in defects in patterns deposited on the substrate.

Embodiments may prevent a mask from adsorbing to the electrostatic chuck for substrate fixation and to improve pixel position accuracy in the deposition process.

A thin film deposition apparatus according to an embodiment may include a chamber, a deposition source disposed in a chamber and that supplies a deposition material to a substrate, a mask assembly comprising pattern holes through which the deposition material passes, and an electrostatic chuck facing the mask assembly in a third direction corresponding to a thickness direction of a substrate with the substrate interposed between the electrostatic chuck and the mask assembly, and that fixes the substrate. The electrostatic chuck may include a body that supports the substrate, an insulating layer disposed on the body, a first electrode disposed in the insulating layer and spaced apart from the body by a first distance in the third direction, a second electrode disposed in the insulating layer and spaced apart from the body by a second distance in the third direction, and a conductive layer disposed in the insulating layer and spaced apart from the body by a third distance in the third direction. The first electrode and the second electrode may be supplied with different voltages, and the third distance may be greater than the first distance.

The first electrode and the second electrode may be alternately disposed in plan view.

The first distance and the second distance may be same.

The conductive layer may include a non-magnetic metal.

The insulating layer may include a first insulating layer disposed on the body, and a second insulating layer disposed on the first insulating layer. The first electrode and the second electrode may be disposed in the first insulating layer, and the conductive layer may be disposed in the second insulating layer.

The first insulating layer may include a material different from a material of the second insulating layer.

The electrostatic chuck may adsorb a substrate in which a plurality of cells are disposed, and the conductive layer may overlap the plurality of cells in plan view.

The electrostatic chuck may adsorb a substrate in which a plurality of cells are disposed, and the conductive layer may overlap a region of the substrate in which the plurality of cells are not disposed in plan view.

The electrostatic chuck may adsorb a substrate in which a plurality of cells are disposed, and the conductive layer may overlap a specific cell among the plurality of cells in plan view.

The electrostatic chuck may adsorb a substrate in which a plurality of cells are disposed, and the conductive layer may overlap a boundary surrounding a specific cell among the plurality of cells in plan view.

The mask assembly may include a frame including an opening, first support sticks disposed on the frame and extending in the first direction, second support sticks disposed on the first support sticks and extending in a second direction intersecting the first direction, and masks disposed on the second support sticks, extending in the first direction, and including a plurality of cells in which the pattern holes are formed.

The conductive layer may overlap the first support sticks of the mask assembly in plan view.

The conductive layer may overlap the second support sticks of the mask assembly in plan view.

The conductive layer may overlap at least a portion of the plurality of cells of the masks.

The conductive layer may overlap at least one of the masks in plan view.

An electrostatic chuck according to an embodiment may include a body that supports a substrate, an insulating layer disposed on the body, a first electrode disposed in the insulating layer and spaced apart from the body by a first distance in a thickness direction of the substrate, a second electrode disposed in the insulating layer and spaced apart from the body by a second distance in the thickness direction of the substrate from the body, and a conductive layer disposed in the insulating layer and spaced apart from the body by a third distance in the thickness direction of the substrate. The first electrode and the second electrode may be supplied with different voltages, and the third distance may be greater than the first distance.

The first electrode and the second electrode may be alternately disposed in plan view.

The first distance and the second distance may be same.

The insulating layer may include a first insulating layer disposed on the body, and a second insulating layer disposed on the first insulating layer, the first electrodes and the second electrode may be disposed in the first insulating layer, and the conductive layer may be disposed in the second insulating layer.

The conductive layer may include a non-magnetic metal.

According to some embodiments, it is possible to prevent the mask from being adsorbed to the electrostatic chuck for fixing the substrate.

In some embodiments, by including the conductive layer in the electrostatic chuck, the effect of electrostatic force on the mask can be reduced.

In some embodiments, defect in a deposition process may be reduced by reducing an alignment error between the substrate and the mask.

### BRIEF DESCRIPTION OF THE DRAWINGS

FIG. 1 is a schematic view of a thin film deposition apparatus according to an embodiment.

FIG. 2 is an exploded schematic perspective view of a mask assembly according to an embodiment.

FIG. 3 is a schematic plan view of an electrostatic chuck according to an embodiment.

FIG. 4 and FIG. 5 each are schematic cross-sectional views of an embodiment taken along A-A′ of FIG. 3.

FIG. 6 is a simulation drawing of an electrostatic force applied to a mask by an electrostatic chuck.

FIG. 7 to FIG. 15 are schematic plan views each illustrating an arrangement of a conductive layer disposed in an electrostatic chuck according to some embodiments.

FIG. 16 is a flowchart for a production process of an electrostatic chuck according to an embodiment.

FIG. 17 is a schematic cross-sectional view schematically illustrating a structure of a display panel according to an embodiment.

### DETAILED DESCRIPTION OF THE EMBODIMENTS

Hereinafter, with reference to the accompanying drawings, various embodiments will be described in detail so that a person of ordinary skill in the art can easily implement them. The disclosure may be implemented in various different forms and is not limited to the embodiments described herein.

In order to clearly describe the embodiments, portions irrelevant to the description have been omitted. Like numbers refer to like elements throughout.

In addition, since the size and thickness of each configuration shown in the drawings may be arbitrarily shown for convenience of description, the embodiments are not necessarily limited to those shown.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

In addition, when a part such as a layer, film, region, plate, etc. is said to be “above” or “on” another part, this includes not only the case where it is “directly on” the other part, but also the case where another part exists in the middle thereof.

In contrast, when an element is referred to as being “directly on” another element, there may be no intervening elements present.

In addition, being “above” or “on” the reference portion is disposed above or below the reference part, and does not necessarily mean that it is disposed “above” or “on” the direction opposite gravity.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In addition, in the specification, when we say “plan”, this means when the target part is viewed from above, and when we say “cross-section”, we mean when the cross-section cut vertically of the target part is viewed from the side.

In the drawing, the numerals “X”, “Y” and “Z” may be used to indicate a direction, wherein “X” may be the first direction, “Y” may be a second direction vertical to the first direction, and “Z” may be a third direction vertical to the first and second directions.

A front surface (or upper surface) and back surface (or bottom surface) of each member may be separated by a third direction Z.

The directions indicated by the first to third directions may be converted to other directions as they may be relative concepts.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

It will be understood that the terms “connected to” or “coupled to” may include a physical and/or electrical connection or coupling.

Although first, second, etc. are used to describe various configurations, it goes without saying that these constituent elements are not limited by these terms. These terms are only used to distinguish one constituent element from another constituent element.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

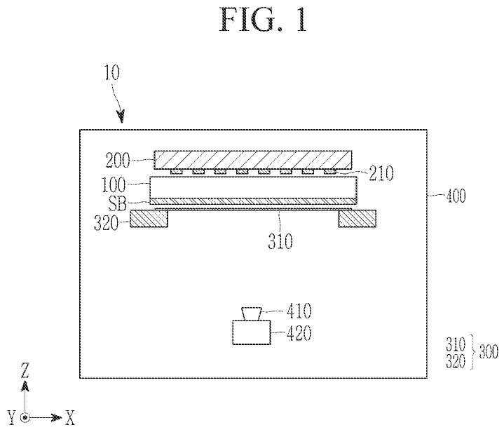

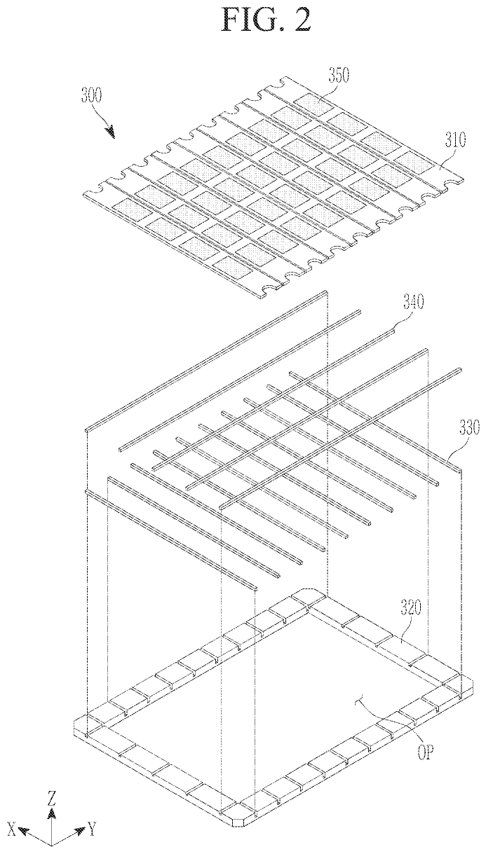

FIG. 1 is a schematic view of a thin film deposition apparatus according to an embodiment. FIG. 2 is an exploded schematic perspective view of a mask assembly according to an embodiment.

Referring to FIG. 1 and FIG. 2, the thin film deposition apparatus 10 according to an embodiment may deposit a thin film on the substrate SB.

By way of example, the thin film deposition apparatus 10 may be used to manufacture an organic light emitting device.

The substrate SB on which a process is performed in the thin film deposition apparatus 10 may include multiple display panels.

The display panels may be organic light emitting panels, quantum dot light emission display panels, etc.

The organic light emitting panels may include organic light emitting elements and emission layers of the organic light emitting elements may include organic light emitting materials.

The thin film may be one of the organic thin films constituting the organic light emitting elements.

For example, the thin film may be an emission layer.

The thin film may be at least one of an electron injection layer, an electron transport layer, a hole transport layer, and a hole injection layer.

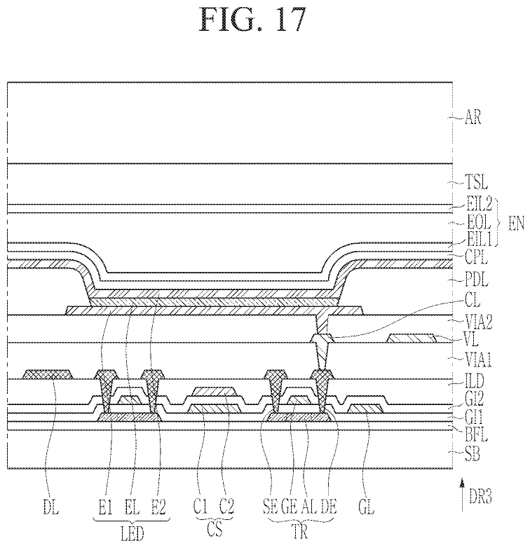

A structure of the display panel according to an embodiment will be described in FIG. 17.

Referring to FIG. 1, the thin film deposition apparatus 10 may include a chamber 400, a deposition source 420, a nozzle unit 410, a mask assembly 300, an electrostatic chuck 100, and a magnetic unit 200.

The chamber 400 may form an internal space in which the deposition process is performed.

The chamber 400 may maintain a vacuum state so that foreign particles do not inflow from the outside and to ensure the straightness of the deposition material.

The deposition source 420 may be located in the chamber 400.

The deposition source 420 may be disposed in the lower space inside the chamber 400.

The deposition source 420 may include a deposition material.

The deposition material may include an organic material.

The deposition material may be liquid state or solid state at room temperature.

The nozzle unit 410 is connected to the deposition source 420 and may include multiple nozzles.

The deposition material provided from the deposition source 420 may be vaporized and sprayed in the upper direction through the nozzle unit 410.

The mask assembly 300 may be disposed over the nozzle unit 410.

The deposition material sprayed from the nozzle unit 410 may move within the space between the nozzle unit 410 and the mask assembly 300 and may be provided to the mask assembly 300.

The structure of the mask assembly 300 will be described below with reference to FIG. 2.

The electrostatic chuck 100 may support and fix the substrate SB in which the process is performed in the chamber 400.

The substrate SB may be a mother substrate including multiple cells corresponding to multiple display panels including organic light emitting elements, and may be a target substrate on which a deposition material is deposited in a deposition process.

The electrostatic chuck 100 may be disposed on the substrate SB and may face the mask assembly 300 with the substrate SB in between.

The electrostatic chuck 100 may include multiple electrodes and may generate an electrostatic force.

The substrate SB may be closely adhered to and fixed to the electrostatic chuck 100 by electrostatic force.

The magnetic unit 200 may be disposed on the electrostatic chuck 100.

The magnetic unit 200 may include multiple magnets 210 at the bottom.

The magnets 210 may add a magnetic force to the electrostatic chuck 100.

In the deposition method using the mask assembly 300, since the pattern of the mask assembly 300 should be aligned very precisely, it is desirable to adhere as closely as possible between the mask assembly 300 and the substrate SB to improve the precision of the deposition pattern deposited on the substrate SB by the pattern of the mask assembly 300.

The mask assembly 300 made of metal may be closely adhered to the substrate SB by the magnetic force of the magnetic unit 200.

In case that the deposition source 420 in the chamber 400 sprays the deposition material through the nozzle unit 410, the deposition material passes through the pattern hole formed in the mask 310 and may be deposited on the substrate SB to form a thin film of a predetermined or selected pattern.

In the organic light emitting device, each pattern region 350 of the mask 310 may correspond to each cell disposed on the substrate SB.

Each cell of the substrate SB may correspond to a display panel.

As described above, the thin film deposition apparatus 10 may include the electrostatic chuck 100 for fixing the substrate, and the magnetic unit 200 for closely adhering the mask assembly 300 to the substrate SB by adding magnetic force from the top of the electrostatic chuck 100.

In an embodiment, the thin film deposition apparatus 10 may fix the substrate SB to the electrostatic chuck 100, and adhere the mask assembly 300 to the substrate SB by using the magnetic force of the magnetic unit 200.

Accordingly, the substrate SB and the mask 310 may be closely adhered to maintain pixel pattern accuracy during the deposition process.

Even in case that the magnetic force of the magnetic unit 200 is not added, a part of the mask 310 may be adsorbed to the substrate SB by the electrostatic force of the electrostatic chuck 100.

Positions of the substrate SB and the mask assembly 300 may be misaligned in a subsequent process, and thus pixel position accuracy may deteriorate, resulting in defects in patterns deposited on the substrate SB.

In an embodiment, adsorption of the mask 310 by the electrostatic force of the electrostatic chuck 100 may be prevented and pixel position accuracy may be improved.

FIG. 2 is an exploded schematic perspective view of a mask assembly used in the thin film deposition apparatus of FIG. 1.

The mask assembly 300 may include a frame 320, first support sticks 330, second support sticks 340, and a mask 310.

The frame 320 may be approximately quadrangle with an opening OP.

On each side of the frame 320, grooves may be formed to accommodate the first support sticks 330 and the second support sticks 340.

The frame 320 may be formed of a material with strong rigidity and little deformation to fix the mask 310.

For example, the frame 320 may be formed of an alloy such as Invar or stainless steel.

The first support sticks 330 may be disposed across the opening OP of the frame 320 in the first direction X and may be fixed to the frame 320.

The light direction of the first support sticks 330 may be parallel to the first direction X.

The first support sticks 330 may be fixed on the frame 320 and disposed below the second support sticks 340.

The first support sticks 330 may support the second support sticks 340 and may indirectly support the masks 310.

The first support sticks 330 may close the gap between adjacent masks 310 and may be referred to as a crevice stick.

The first support sticks 330 may prevent the depositing material from being deposited to the mother substrate through the gap between the masks 310.

The second support sticks 340 may be disposed across the opening OP of the frame 320 in the second direction Y and may be fixed to the frame 320.

The second support sticks 340 may have a length direction (or referred to as an extension direction) parallel to the second direction Y.

In an embodiment, the second support sticks 340 may be disposed in the long side direction of the mother substrate and may be referred to as long side sticks.

The second support sticks 340 may support the masks 310.

By the second support sticks 340, the masks 310 may be divided into pattern regions 350 of the unit cell.

The pattern region 350 of the unit cell may correspond to one display panel.

The pattern region 350 may be formed corresponding to the shape of the display panel.

The pattern region 350 may be, for example, a rectangular shape, and the edge corner may have a round shape.

The first support sticks 330 and the second support sticks 340 may be formed of an alloy such as a metal, for example stainless steel.

The masks 310 may be positioned across the opening OP of the frame 320 in the first direction X and may be fixed to the frame 320.

The masks 310 may be fixed to the frame 320 through welding while being stretched in a length direction of the mask 310.

Each of the masks 310 may be in the form of a stick, and the masks 310 may be combined to form a mask assembly corresponding to one mother substrate.

Each mask 310 may be referred to as a split mask or a mask stick.

Each mask 310 may include multiple pattern regions 350 corresponding to multiple cells.

Each pattern region 350 may include through-holes corresponding to a pattern of certain colored emission layers e.g., red emission layers, green emission layers, or blue emission layers) to be formed, for example, in each cell of the mother substrate.

The masks 310 may be formed of a metal or a metal alloy, such as Invar or stainless steel.

The masks 310 may be referred to as a fine metal mask (FMM).

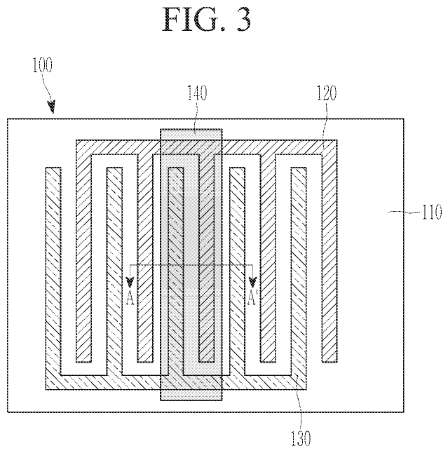

FIG. 3 is a schematic plan view of an electrostatic chuck according to an embodiment.

FIG. 4 is a schematic cross-sectional view of an embodiment taken along A-A′ of FIG. 3.

Referring to FIG. 3 and FIG. 4, the electrostatic chuck 100 according to an embodiment may include a body 110 and a first insulating layer 151 disposed on the body 110.

The first insulating layer 151 may be positioned on a side of the body 110.

The first insulating layer 151 may be in contact with the bottom surface of the body 110 (i.e., the bottom surface based on the third direction Z, which is the thickness direction of the substrate).

The body 110 may support the substrate that is an adsorption object.

The size of the body 110 may be the same as or larger than the substrate.

The body 110 of the electrostatic chuck 100 may be quadrangular in plan view, and may have various shapes such as a round, oval, and polygon corresponding to the shape of the adsorption object.

The body 110 may include a metal such as graphite, aluminum (Al), and stainless steel.

The first insulating layer 151 may be disposed on the bottom surface of the body 110.

The first insulating layer 151 may include materials having excellent electrical insulation and chemical stability (e.g., ceramic, alumina, etc.).

The first insulating layer 151 may include a first electrode 120 and a second electrode 130, to which different voltages are applied, and a conductive layer 140.

Multiple first electrodes 120 and second electrodes 130 may be provided, and may be alternately arranged in plan view.

Referring to FIG. 4, the first electrode 120 may be spaced away from the body 110 by a first distance d1 in the third direction Z, and the second electrode 130 may be spaced away from the body 110 by a second distance d2 in the third direction Z.

In an embodiment, the first distance d1 and the second distance d2 may be the same.

The first electrode 120 and the second electrode 130 may overlap in the second direction Y which corresponds to a horizontal direction.

The first electrode 120 and the second electrode 130 may be disposed on a same plane.

In an embodiment, the first distance d1 and the second distance d2 may be different.

The first electrode 120 and the second electrode 130 may be disposed on different planes, and may be variously disposed in a parallel configuration, an intersecting configuration, and the like.

The first electrode 120 and the second electrode 130 may be supplied with voltages of different properties.

For example, the first electrode 120 may be supplied with a positive voltage (+), and the second electrode 130 may be supplied with a negative voltage (−).

Accordingly, an electrostatic force caused by the voltages separated applied to both electrodes may be generated.

The substrate SB may be adsorbed to the electrostatic chuck 100 by this electrostatic force.

In case that voltages are supplied to the electrostatic chuck 100, an electrostatic force may be extended to the masks 310 positioned below the substrate SB.

Some of the masks 310 may adhere to the substrate SB, and thereafter the alignment between the substrate SB and the mask 310 in the deposition process may be distorted.

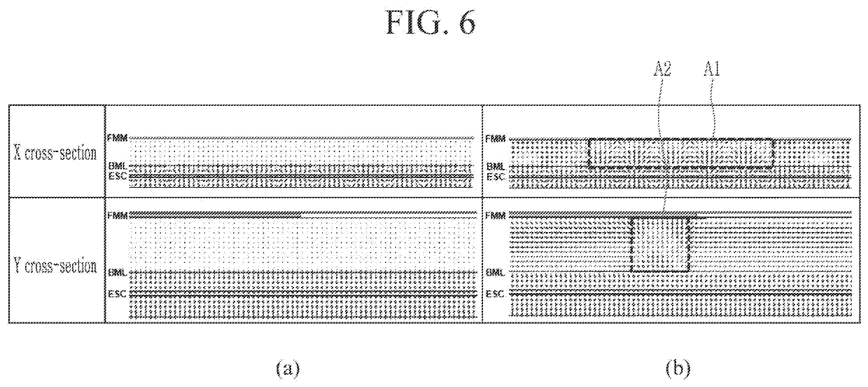

The electrostatic force of the electrostatic chuck 100 on the masks 310 will be further described with reference to FIG. 6.

In an embodiment, the electrostatic chuck 100 may include a conductive layer 140.

The conductive layer 140 may include metal.

The conductive layer 140 may be a non-magnetic metal and may include, for example, aluminum (Al), silver (Ag), gold (Au), copper (Cu), and the like.

Voltage may not be applied to the conductive layer 140.

The conductive layer 140 may be implemented as a floating metal portion that is not electrically connected to the surroundings.

Referring to FIG. 3, the conductive layer 140 may have a rectangular shape and may be disposed at the center of the electrostatic chuck 100.

According to an embodiment, the shape and arrangement of the conductive layer 140 may be variously changed.

The conductive layer 140 may have various arrangements in relation to the substrate SB or the mask assembly 300.

Referring to FIG. 4, the conductive layer 140 may be positioned below the first electrode 120 and the second electrode 130 in cross-sectional view.

The conductive layer 140 may be spaced apart from the body by a third distance d3 in the third direction Z.

In an embodiment, the third distance d3 from the body 110 to the conductive layer 140 may be larger than the first distance d1 from the body 110 to the first electrode 120 and/or the second distance d2 from the body 110 to the second electrode 130.

For example, the conductive layer 140 may be positioned in a plane different from that of the first electrode 120 and/or the second electrode 130, and may be positioned below the first electrode 120 and/or the second electrode 130 in the third direction Z.

Accordingly, the conductive layer 140 may block the electrostatic force generated between the first electrode 120 and the second electrode 130 from affecting the bottom of the conductive layer 140.

The conductive layer 140 may have various shapes and may be variously arranged in relation to the substrate SB and/or the mask assembly 300.

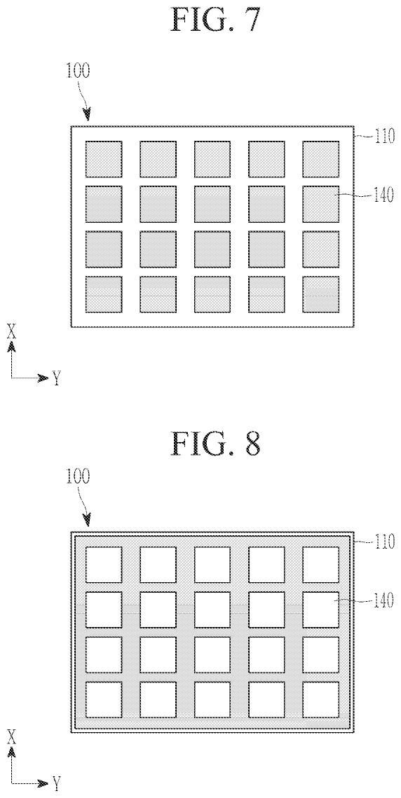

The planar arrangement of the conductive layer 140 will be further described through FIG. 7 to FIG. 15.

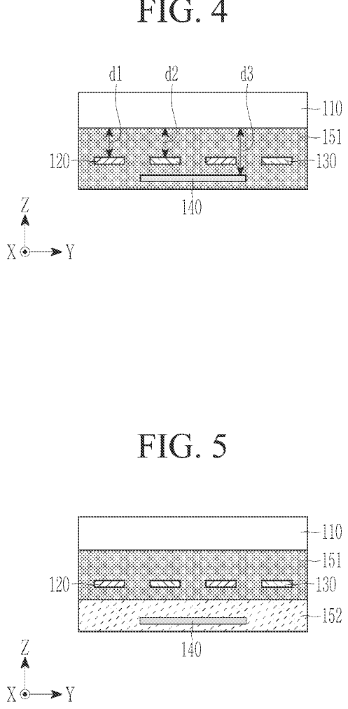

FIG. 5 is a schematic cross-sectional view of an embodiment taken along A-A′ of FIG. 3.

An embodiment of FIG. 5 may differ from an embodiment of FIG. 4 at least in that it includes a second insulating layer 152.

A detailed description of the same constituents as shown in FIG. 4 will be omitted.

Referring to FIG. 5, the second insulating layer 152 may be disposed on the first insulating layer 151.

The second insulating layer 152 may be disposed in contact with the bottom surface of the first insulating layer 151 (i.e., the surface facing the target substrate).

The first insulating layer 151 may include a first electrode 120 and a second electrode 130 to which voltages of different properties are applied.

The second insulating layer 152 may include a conductive layer 140 for shielding the electrostatic force generated by the first electrode 120 and the second electrode 130.

Voltage may not be applied to the conductive layer 140.

In an embodiment of FIG. 5, the conductive layer 140 may be disposed in the second insulating layer 152, which is a layer distinct from the first insulating layer 151 including the first electrode 120 and the second electrode 130.

Accordingly, the first insulating layer 151 including the first electrode 120 and the second electrode 130 may be left untouched, and only the second insulating layer 152 may be removed to facilitate redisposition of the conductive layer 140.

FIG. 6 is a simulation drawing of an electrostatic force applied to a mask by an electrostatic chuck.

In FIG. 6, ESC denotes an electrostatic chuck, BML denotes a conductive layer formed on a substrate, and FMM denotes a mask.

Regions A1 and A2 indicate the regions in the substrate where the conductive layer is not formed.

The X cross-section is a cross-section cut along the first direction X, and the Y cross-section means a section cut along the second direction Y.

Referring to FIG. 6, the electrostatic chuck ESC, the conductive layer BML of the substrate, and the mask FMM are disposed in turn from the bottom.

In case that voltages are applied to the electrostatic chuck, the substrate can be adsorbed to the electrostatic chuck by an electrostatic force.

FIG. 6 (a) is a simulation drawing showing an electrostatic force in case that the conductive layer BML is formed as a whole on the substrate, and FIG. 6 (b) is a simulation drawing showing an electrostatic force in case that the substrate includes the regions A1 and A2 in which the conductive layer BML is not formed.

Referring to FIG. 6 (a), the electrostatic force generated in the electrostatic chuck ESC may be blocked by the conductive layer BML formed on the substrate and may not be provided to the mask FMM.

Referring to FIG. 6 (b), it can be confirmed that the electrostatic force generated in the electrostatic chuck ESC may be applied to the mask FMM in the region A1 and the region A2, which are the regions in which the conductive layer BML formed on the substrate may not be disposed.

A part of the mask FMM is pulled toward the electrostatic chuck ESC by this electrostatic force, and a mask adsorption phenomenon may occur.

Embodiments may prevent the mask adsorption by the electrostatic force by disposing the conductive layer capable of shielding electrostatic force in a predetermined or selected area, thereby improving pixel position accuracy in the deposition process to prevent defects.

FIG. 7 to FIG. 15 are schematic plan views each illustrating an arrangement of a conductive layer included in an electrostatic chuck according to an embodiment.

FIG. 7 is an embodiment in which a conductive layer 140 is disposed to correspond to multiple cells disposed on a substrate.

The substrate may include multiple cells corresponding to multiple display panels comprising organic light emitting elements.

Referring to FIG. 7, the conductive layer 140 may be disposed to correspond to an area corresponding to multiple display panels disposed on a substrate.

Accordingly, in case that the substrate SB is fixed to the electrostatic chuck 100, the cell region of the substrate SB (for example, the area in which the deposition material is deposited in the area where the display panel is placed) may overlap the conductive layer 140 of the electrostatic chuck 100 in plan view.

Accordingly, by preventing the mask from being adsorbed to the cell region of the substrate SB by electrostatic force, misalignment of the substrate and the mask in a subsequent process can be prevented and the precision of the deposition pattern can be improved.

FIG. 8 is an embodiment of disposing a conductive layer 140 in an area other than multiple cells disposed on a substrate.

For example, the conductive layer 140 may be disposed to correspond to the peripheral area excluding the display panel region of the substrate in plan view.

Accordingly, in case that the substrate SB is fixed to the electrostatic chuck 100, the conductive layer 140 of the electrostatic chuck 100 and the region excluding the cell region of the substrate SB (e.g., the region in which the display panel is disposed) may overlap in plan view.

The cell region of the substrate SB may be a region corresponding to the display panel, and various conductive layers may be disposed in the cell region.

On the other hand, since no conductive layer may be placed at the cell boundary or in the peripheral area, the electrostatic force can extend to the mask.

The conductive layer 140 may be disposed in this region to prevent adsorption of the mask by electrostatic force.

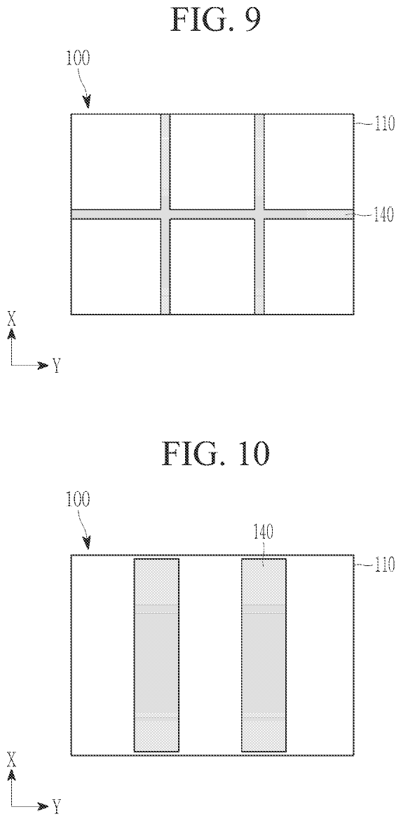

FIG. 9 is an embodiment of arranging a conductive layer to correspond to a photo shot boundary region of a substrate.

For example, in case that a large mother substrate is used, the photo process may be divided into partial processes.

The conductive layer 140 of the electrostatic chuck 100 may be disposed to correspond to the photo shot boundary region of the substrate during partial processing.

For example, in case that the substrate SB is fixed to the electrostatic chuck 100, the conductive layer 140 of the electrostatic chuck 100 may overlap the photo shot boundary region of the substrate SB.

Since a conductive layer may not be disposed at the boundary of the photo shot, the conductive layer can be arranged to correspond to the boundary of the photo shot to prevent mask adsorption by electrostatic force.

For example, FIG. 9 shows that in case that the photo process proceeds with a partial process of six photo shots, the conductive layer 140 is disposed to correspond to the boundaries of the six partition regions.

In an embodiment, the partition regions may be variously applied according to the partial process of the photo shot such as 2 or 4 times.

FIG. 10 relates to an embodiment of arranging a conductive layer in a section of a specific mask.

The conductive layer 140 may be disposed to correspond to a region of a particular mask of the mask assembly.

For example, in case that the mask assembly is closely adhered to the substrate by the magnetic unit, the conductive layer 140 of the electrostatic chuck 100 may be arranged to overlap a specific mask region in plan view.

The conductive layer 140 may be disposed in a specific mask region to prevent adsorption of the mask by electrostatic force.

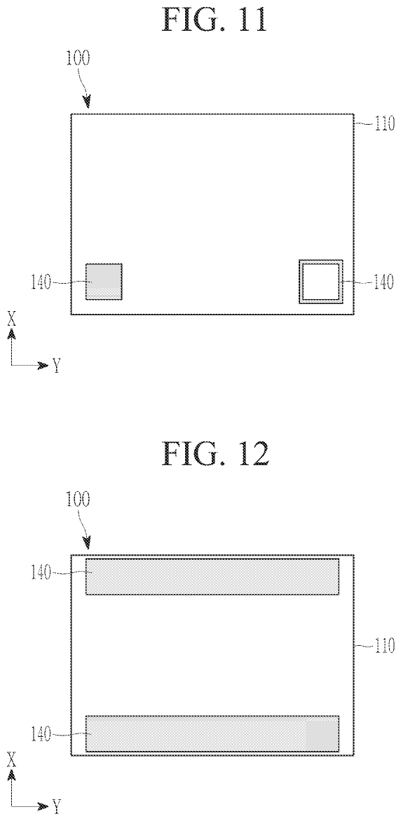

FIG. 11 is an embodiment of disposing a conductive layer only in a specific cell region or a peripheral area of the cell.

The conductive layer 140 may be disposed in a region corresponding to a specific display panel of the substrate, or may be disposed to correspond to a peripheral area of the specific display panel.

For example, in case that the substrate SB is adsorbed on the electrostatic chuck 100, the conductive layer 140 of the electrostatic chuck 100 may overlap a region corresponding to a specific display panel of the substrate and/or a peripheral area of a specific display panel in plan view.

For example, the conductive layer 140 may be disposed to overlap a cell region disposed at a corner or a corner portion to prevent adsorption of the mask by electrostatic force.

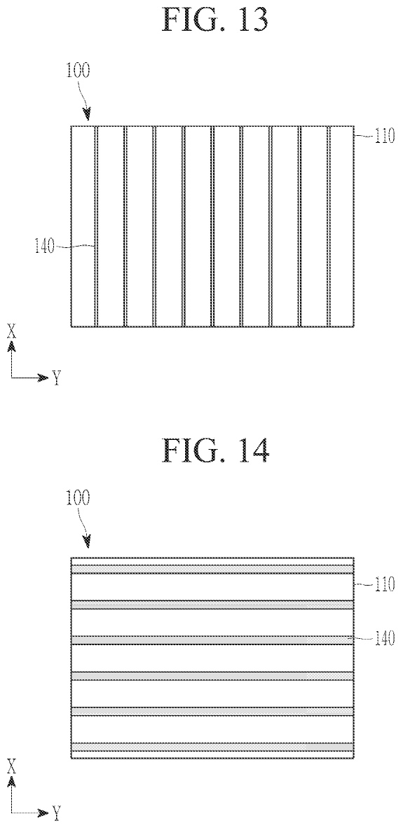

FIG. 12 is an embodiment in which a conductive layer is placed in first and last rows of masks.

The conductive layer 140 may be disposed to overlap pattern regions arranged along the second direction Y of the mask assembly in plan view.

For example, as shown in FIG. 12, the conductive layer 140 may be disposed to correspond to the regions corresponding to the long side first row and last row of masks.

The conductive layer 140 may be disposed to correspond to at least one edge row of both long sides of the mask assembly.

Accordingly, adsorption of the mask by electrostatic force can be prevented.

FIG. 13 is an embodiment in which conductive layers are arranged to correspond to the positions of the first support sticks (e.g., crevice sticks) of the mask assembly.

FIG. 14 is an embodiment in which conductive layers are arranged to correspond to the positions of the second support sticks of the mask assembly.

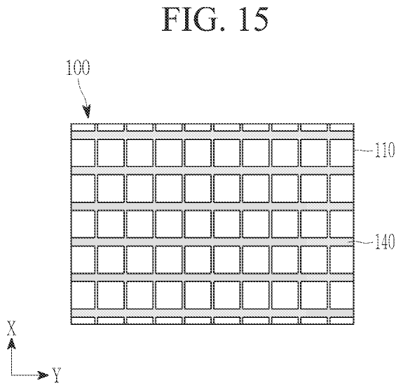

FIG. 15 is an embodiment in which conductive layers are arranged to correspond to the positions of the first and second support sticks of the mask assembly.

For example, in case that the mask assembly is closely attached to the substrate by the magnetic unit, the conductive layer 140 of the electrostatic chuck 100 may be disposed to overlap the first support sticks (e.g., crevice sticks) of the mask assembly, or may be disposed to overlap the second support sticks (e.g., long side sticks) of the mask assembly, or may be disposed to overlap both the first and second support sticks of the mask assembly.

As described above, since the electrostatic chuck 100 according to an embodiment includes the conductive layer 140 below the first electrode and the second electrode, the electrostatic force of the electrostatic chuck 100 may not reach the mask disposed at the bottom of the substrate SB.

Accordingly, in case that the electrostatic chuck 100 fixes the substrate, mask adsorption by electrostatic force can be prevented, and pixel position accuracy can be improved in the deposition process.

The conductive layer 140 may be disposed according to various embodiments in a corresponding relationship with the substrate and/or mask assembly.

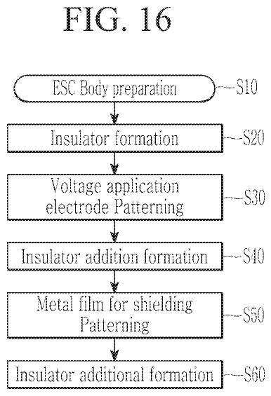

FIG. 16 is a flowchart for a production process of an electrostatic chuck according to an embodiment.

A first operation may include preparing the body of the electrostatic chuck (S10).

An insulating layer may be formed on the body of the electrostatic chuck (S20).

A first electrode and a second electrode for applying voltages may be formed on the insulating layer.

The first electrode and the second electrode may be formed in one process or may be formed in different processes.

The first electrode and the second electrode may be formed through a patterning process of a metal layer (S30).

An insulating layer may be further formed on the patterned first electrode and the second electrode (S40).

Thereafter, a conductive layer may be formed to shield an electrostatic force on the insulating layer.

For example, the conductive layer may be formed by patterning a metal film for shielding (S50).

Thereafter, an insulating layer may be further formed (S60).

The insulating layer on the shielding metal film may be formed of a different material or the same material as the insulating layer on the electrode.

As described above, the electrostatic chuck may include the conductive layer under the patterned electrode, which can prevent the mask from being adsorbed together during substrate adsorption by the electrostatic chuck, and subsequently reduce defects in the deposition process.

FIG. 17 is a schematic cross-section view schematically illustrating a structure of a display panel according to an embodiment.

The cells formed on the mother substrate through a deposition process or the like may be divided and used as display panels of the display devices.

The cross-section shown in FIG. 17 may correspond to approximately one pixel area.

The display panel may include a substrate SB, a transistor TR formed on the substrate, and a light emitting diode LED connected to a transistor TR.

The light-emitting diode LED may correspond to pixels.

The substrate SB may be made of a material such as glass.

The substrate SB may be a flexible substrate comprising a polymer resin such as polyimide, polyamide, polyethylene terephthalate, and/or the like.

A buffer layer BFL may be positioned on the substrate SB.

The buffer layer BFL can improve the characteristics of the semiconductor layer by blocking impurities from the substrate SB during the formation of the semiconductor layer, and relieve the stress of the semiconductor layer by flattening the surface of the substrate SB.

A semiconductor layer AL of the transistor TR may be positioned on the buffer layer.

The semiconductor layer AL may include a first region, a second region, and a channel region between these regions.

The semiconductor layer AL may include at least one of amorphous silicon, polycrystalline silicon, and oxide semiconductor.

For example, the semiconductor layer AL may include low temperature crystalline silicon (LTPS) or may include an oxide semiconductor material comprising at least one of zinc (Zn), indium (In), gallium (Ga), and tin (Sn).

The first gate insulating layer GI1 may be positioned on the semiconductor layer AL.

The first gate insulating layer GI1 may include an inorganic insulating material such as silicon nitride, silicon oxide, and/or silicon nitroxide, and may be a single layer or multiple layers.

A first gate conductive layer, which may include a gate electrode GE of the transistor TR, a gate line GL, a first electrode C1 of a capacitor CS, and the like, may be positioned on the first gate insulating layer GI1.

The first gate conductive layer may include molybdenum (Mo), aluminum (Al), copper (Cu), titanium (Ti), and/or the like, and may be single layer or multiple layers.

A second gate insulating layer GI2 may be positioned on the first gate conductive layer.

The second gate insulating layer GI2 may include an inorganic insulating material such as silicon nitride, silicon oxide, and/or silicon nitroxide, and may be a single layer or multiple layers.

A second gate conductive layer, which may include a second electrode C2 of the capacitor CS or the like, may be disposed on the second gate insulating layer GI2.

The second gate conductive layer may include molybdenum (Mo), aluminum (Al), copper (Cu), titanium (Ti), and/or the like, and may be a single layer or multiple layers.

An interlayer insulating layer ILD may be positioned on the second gate insulating layer GI2 and the second gate conductive layer.

The interlayer insulating layer ILD may include an inorganic insulating material such as silicon nitride, silicon oxide, silicon nitroxide, and may be a single layer or multiple layers.

A first data conductive layer, which may include a first electrode SE and a second electrode DE of the transistor TR, a data line DL, and the like, may be positioned on the interlayer insulating layer ILD.

The first electrode SE and the second electrode DE may be connected to the first and second regions of the semiconductor layer AL through contact holes formed in the insulating layers GI1, GI2, and ILD, respectively.

One of the first electrode SE and the second electrode DE may be a source electrode and the other may be a drain electrode.

The first data conductive layer may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and/or the like, and may be a single layer or multiple layers.

A first planarization layer VIA1 may be positioned on the first data conductive layer.

The first planarization layer VIA1 may be an organic insulating layer.

For example, the first planarization layer VIA1 may include general purpose polymers such as polymethylmethacrylate and polystyrene, polymer derivatives having phenolic groups, acryl-based polymers, imide polymers (e.g., polyimides), siloxane-based polymers, and/or the like.

A second data conductive layer, which may include a voltage line VL, a connection line CL, and the like, may be positioned on the first planarization layer VIA1.

The voltage line VL can carry voltages such as a drive voltage, a common voltage, an initialization voltage, and a reference voltage.

The connecting line CL may be connected to the second electrode DE of the transistor TR through a contact hole formed in the first planarization layer VIA1. The second data conductive layer may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and/or the like, and may be a single layer or multiple layers.

A second planarization layer VIA2 may be positioned on the second data conductive layer.

The second planarization layer VIA2 may be an organic insulating layer.

For example, the second planarization layer VIA2 may include general purpose polymers such as polymethyl methacrylate and polystyrene, polymer derivatives having phenolic groups, acryl-based polymers, imide polymers (e.g., polyimides), siloxane-based polymers, and/or the like.

A first electrode E1 of the light emitting diode LED may be positioned on the planarization layer VIA2.

The first electrode E1 may be referred to as a pixel electrode.

The first electrode E1 may be connected to the connecting wire CL through a contact hole formed in the second planarization layer VIA2.

Therefore, the first electrode E1 may be electrically connected to the second electrode DE of the transistor TR and may receive a current to control the brightness of the light emitting diode.

The transistor TR to which the first electrode E1 is connected may be a driving transistor or a transistor electrically connected to the drive transistor.

The first electrode E1 may be formed of a reflective conductive material or a semi-permeable conductive material, and may be formed of a transparent conductive material.

The first electrode E1 may include a transparent conductive material such as indium tin oxide (ITO) and indium zinc oxide (IZO).

The first electrode E1 may include a metal or metal alloy such as lithium (Li), calcium (Ca), aluminum (Al), silver (Ag), magnesium (Mg), and/or gold (Au).

A pixel definition layer PDL, which may be an organic insulating layer, may be positioned on the second planarization layer VIA2.

The pixel definition layer PDL may be referred to as a partition or bank and may have an opening overlapping the first electrode E1.

A light-emitting layer EL of the light emitting diode LED may be positioned on the first electrode E1.

In addition to the light emitting layer EL, at least one of a hole injection layer, a hole transport layer, an electron transport layer, and an electron injection layer may be positioned on the first electrode E1.

The thin film deposition apparatus described above can be used to deposit the light emitting layer EL.

A second electrode E2 of the light emitting diode LED may be positioned on the light emitting layer EL.

The second electrode E2 may be referred to as a common electrode.

The second electrode E2 may have light transmission by forming a thin layer of a metal or metal alloy with a low working function such as calcium (Ca), barium (Ba), magnesium (Mg), aluminum (Al), and/or silver (Ag).

The second electrode E2 may include a transparent conductive oxide such as indium tin oxide (ITO) and indium zinc oxide (IZO).

The first electrode E1, the light-emitting layer EL, and the second electrode E2 of each pixel may form the light emitting diode LED such as an organic light-emitting diode.

The first electrode E1 may be an anode of the light emitting diode LED, and the second electrode E2 may be a cathode of the light emitting diode LED.

A capping layer CPL may be positioned on the second electrode E2.

The capping layer CPL can increase the light efficiency by adjusting a refractive index.

The capping layer CPL may be positioned to cover the second electrode E2 as a whole.

The capping layer CPL may include an organic insulating material and/or an inorganic insulating material.

An encapsulation layer EN may be positioned on the capping layer CPL.

The encapsulation layer EN may encapsulate the light emitting diode LED to prevent moisture or oxygen from penetrating from the outside.

The encapsulant layer EN may be a thin film encapsulation layer comprising one or more inorganic layers EIL1 and EIL2 and one or more organic layers EOL.

A touch sensor layer TSL including touch electrodes may be positioned on the encapsulant layer EN.

The touch electrodes may be a mesh shape having an opening overlapping the light emitting diode LED.

An anti-reflection layer AR may be positioned on the touch sensor layer TSL to reduce external light reflection.

While this disclosure has been described in connection with what is considered to be practical embodiments, it is to be understood that the disclosure is not limited to the disclosed embodiments, but, on the contrary, is intended to cover various modifications and equivalent arrangements included within the spirit and scope of the disclosure.

What is claimed is:

1. A thin film deposition apparatus, comprising:
a chamber;
a deposition source disposed in the chamber and that supplies a deposition material to a substrate;
a mask assembly comprising pattern holes through which the deposition material passes; and
an electrostatic chuck facing the mask assembly in a third direction corresponding to a thickness direction of the substrate, with the substrate interposed between the electrostatic chuck and the mask assembly, and that fixes the substrate, wherein
the electrostatic chuck comprises:
a body that supports the substrate;
an insulating layer disposed on the body;
a first electrode disposed in the insulating layer and spaced apart from the body by a first distance in the third direction;
a second electrode disposed in the insulating layer and spaced apart from the body by a second distance in the third direction; and
a conductive layer disposed in the insulating layer and spaced apart from the body by a third distance in the third direction,
the first electrode and the second electrode are supplied with different voltages, and
the third distance is greater than the first distance.

2. The thin film deposition apparatus of claim 1, wherein the first electrode and the second electrode are alternately disposed in plan view.

3. The thin film deposition apparatus of claim 1, wherein the first distance and the second distance are same.

4. The thin film deposition apparatus of claim 1, wherein the conductive layer comprises a non-magnetic metal.

5. The thin film deposition apparatus of claim 1, wherein
the insulating layer comprises:
a first insulating layer disposed on the body; and
a second insulating layer disposed on the first insulating layer,
the first electrode and the second electrode are disposed in the first insulating layer, and
the conductive layer is disposed in the second insulating layer.

6. The thin film deposition apparatus of claim 5, wherein the first insulating layer comprises a material different from a material of the second insulating layer.

7. The thin film deposition apparatus of claim 1, wherein
the electrostatic chuck adsorbs a substrate in which a plurality of cells are disposed, and
the conductive layer overlaps the plurality of cells in plan view.

8. The thin film deposition apparatus of claim 1, wherein
the electrostatic chuck adsorbs a substrate in which a plurality of cells are disposed, and
the conductive layer overlaps a region of the substrate in which the plurality of cells are not disposed in plan view.

9. The thin film deposition apparatus of claim 1, wherein
the electrostatic chuck adsorbs a substrate in which a plurality of cells are disposed, and
the conductive layer overlaps a specific cell among the plurality of cells in plan view.

10. The thin film deposition apparatus of claim 1, wherein
the electrostatic chuck adsorbs a substrate in which a plurality of cells are disposed, and
the conductive layer overlaps a boundary surrounding a specific cell among the plurality of cells in plan view.

11. The thin film deposition apparatus of claim 1, wherein
the mask assembly comprises:
a frame comprising an opening;
first support sticks disposed on the frame and extending in a first direction;
second support sticks disposed on the first support sticks and extending in a second direction intersecting the first direction; and
masks disposed on the second support sticks, extending in the first direction, and comprising a plurality of cells in which the pattern holes are formed.

12. The thin film deposition apparatus of claim 11, wherein the conductive layer overlaps the first support sticks of the mask assembly in plan view.

13. The thin film deposition apparatus of claim 11, wherein the conductive layer overlaps the second support sticks of the mask assembly in plan view.

14. The thin film deposition apparatus of claim 11, wherein the conductive layer overlaps at least a portion of the plurality of cells of the masks in plan view.

15. The thin film deposition apparatus of claim 11, wherein the conductive layer overlaps at least one of the masks in plan view.

16. An electrostatic chuck, comprising:
a body that supports a substrate;
an insulating layer disposed on the body;
a first electrode disposed in the insulating layer and spaced apart from the body by a first distance in a thickness direction of the substrate;
a second electrode disposed in the insulating layer and spaced apart from the body by a second distance in the thickness direction of the substrate; and
a conductive layer disposed in the insulating layer and spaced apart from the substrate from the body by a third distance in the thickness direction, wherein
the first electrode and the second electrode are supplied with different voltages, and
the third distance is greater than the first distance.

17. The electrostatic chuck of claim 16, wherein the first electrode and the second electrode are alternately disposed in plan view.

18. The electrostatic chuck of claim 16, wherein the first distance and the second distance are same.

19. The electrostatic chuck of claim 16, wherein
the insulating layer comprises:
a first insulating layer disposed on the body; and
a second insulating layer disposed on the first insulating layer,
the first electrode and the second electrode are disposed in the first insulating layer, and
the conductive layer is disposed in the second insulating layer.

20. The electrostatic chuck of claim 16, wherein the conductive layer comprises a nonmagnetic metal.
